(19) United States
(12) Patent Application Publication
(10) Pub. No.: US 2026/0082793 A1
(43) Pub. Date: Mar. 19, 2026

(54) DISPLAY PANEL AND DISPLAY DEVICE

(71) Applicant: WUHAN TIANMA MICROELECTRONICS CO., LTD. SHANGHAI BRANCH, Pudong New District (CN)

(72) Inventor: Xi CHEN, Shanghai (CN)

(21) Appl. No.: 19/363,023

(22) Filed: Oct. 20, 2025

(30) Foreign Application Priority Data
Jun. 9, 2025 (CN) 202510766721.1

(51) Int. Cl. H10K 59/50; H10K 59/40

(52) U.S. Cl. CPC H10K 59/50; H10K 59/40

(57) ABSTRACT

Provided are a display panel and a display device, relating to the field of display technologies. The light modulation assembly is arranged in the region of the slit and includes the first film layer and the second film layer that are stacked in the first direction, and a refractive index of the first film layer is greater than a refractive index of the second film layer. After the large-viewing-angle light emitted by the light-emitting element in the display panel enters the light modulation assembly, total reflection can occur at an interface of the first film layer and the second film layer, and the light may not be refracted out from the interface, so that no light leakage can occur at the slit, thereby improving etching patterns and improving the display effect of the display panel.

### CROSS-REFERENCE TO RELATED APPLICATION

The present disclosure claims priority to Chinese Patent Application No. 202510766721.1, filed on Jun. 9, 2025, the content of which is incorporated herein by reference in its entirety.

### TECHNICAL FIELD

The present disclosure relates to the field of display technologies, and in particular, to a display panel and a display device.

### BACKGROUND

With the continuous development of display technologies, a display panel has become a common way for users to implement human-computer interaction with an electronic device. In order to improve interaction efficiency, the display panel can have a touch function. In order to add the touch function to the display panel, a touch screen is usually arranged on a display side of the display panel, which makes an overall thickness of the entire display device relatively thick and leads to poor user experience.

In order to adapt to the trend of lightness and thinness of the display panel or the display device, a touch function layer can be arranged inside the display panel or the display device.

Usually, a slit is arranged on a touch trace in the touch function layer. Light leakage can occur when a light-emitting element emits large-viewing-angle light at the position of the slit, while other positions on the touch traces without slits will not have light leakage due to their own light shielding, resulting in naked eye seeing relatively regular etching patterns, thereby affecting the display effect of the display panel.

### SUMMARY

In view of the above problems, the present disclosure provides a display panel and a display device to achieve the purpose of improving the display effect of the display panel.

A first aspect of the present disclosure provides a display panel, including: a light modulation assembly and a touch function layer. The touch function layer includes a plurality of touch traces, and at least part of the plurality of touch traces is provided with a slit. The light modulation assembly is located in a region of the slit and includes a first film layer and a second film layer that are stacked in a first direction, a refractive index of the first film layer is greater than a refractive index of the second film layer; and the first direction is perpendicular to a plane of the touch function layer pointing to a light-emitting side of the display panel.

A second aspect of the present disclosure provides a display device including the display panel described above.

By means of the above technical solution, the present disclosure provides a display panel and a display device. The light modulation assembly is arranged in the region of the slit and includes the first film layer and the second film layer that are stacked in the first direction, and a refractive index of the first film layer is greater than a refractive index of the second film layer. After the large-viewing-angle light emitted by the light-emitting element in the display panel enters the light modulation assembly, total reflection can occur at an interface of the first film layer and the second film layer, and the light may not be refracted out from the interface, so that no light leakage can occur at the slit, thereby improving etching patterns and improving the display effect of the display panel.

### BRIEF DESCRIPTION OF DRAWINGS

The above and other features, advantages and aspects of embodiments of the present disclosure will become more apparent with reference to the following detailed description in conjunction with the drawings. Throughout the drawings, the same or similar reference signs denote the same or similar elements. It should be understood that the drawings are schematic and that objects and elements are not necessarily drawn to scale.

FIG. 1 is a schematic layout diagram of a slit according to an embodiment of the present disclosure;

FIG. 2 is a schematic diagram of a special-shaped slit according to an embodiment of the present disclosure;

FIG. 3 is a schematic diagram of a double-layer touch trace according to an embodiment of the present disclosure;

FIG. 4 is a schematic structural diagram of a display panel according to an embodiment of the present disclosure;

FIG. 5 is a schematic cross-sectional view along a cutting line AA′ shown in FIG. 4 according to an embodiment of the present disclosure;

FIG. 6 is a schematic cross-sectional view along a cutting line BB′ shown in FIG. 4 according to an embodiment of the present disclosure;

FIG. 7 is a schematic structural diagram of another display panel according to an embodiment of the present disclosure;

FIG. 8 is a schematic structural diagram of a display function layer according to an embodiment of the present disclosure;

FIG. 9 is a schematic structural diagram of another display panel according to an embodiment of the present disclosure;

FIG. 10 is a schematic cross-sectional view of a display panel according to an embodiment of the present disclosure;

FIG. 11 is a schematic cross-sectional view of another display panel according to an embodiment of the present disclosure;

FIG. 12 is a schematic cross-sectional view of another display panel according to an embodiment of the present disclosure;

FIG. 13 is a schematic cross-sectional view of another display panel according to an embodiment of the present disclosure;

FIG. 14 is a schematic cross-sectional view of another display panel according to an embodiment of the present disclosure;

FIG. 15 is a first partial schematic structural diagram corresponding to a method for preparing a display panel according to an embodiment of the present disclosure;

FIG. 16 is a second partial schematic structural diagram corresponding to a method for preparing a display panel according to an embodiment of the present disclosure;

FIG. 17 is a third partial schematic structural diagram corresponding to a method for preparing a display panel according to an embodiment of the present disclosure;

FIG. 18 is a fourth partial schematic structural diagram corresponding to a method for preparing a display panel according to an embodiment of the present disclosure;

FIG. 19 is a fifth partial schematic structural diagram corresponding to a method for preparing a display panel according to an embodiment of the present disclosure;

FIG. 20 is a schematic cross-sectional view of another display panel according to an embodiment of the present disclosure;

FIG. 21 is a schematic structural diagram of another display panel according to an embodiment of the present disclosure;

FIG. 22 is a schematic structural diagram of another display panel according to an embodiment of the present disclosure; and

FIG. 23 is a schematic structural diagram of a display device according to an embodiment of the present disclosure.

### DESCRIPTION OF EMBODIMENTS

Embodiments of the present disclosure are described as follows with reference to the drawings in the embodiments of the present disclosure. Terms used in the embodiments of the present disclosure are merely used to explain specific embodiments of the present disclosure and are not intended to limit the present disclosure. Those skilled in the art can know that, with the development of technologies and the emergence of new scenarios, the technical solutions provided in the embodiments of the present disclosure are also applicable to similar technical problems.

It should be noted that orientation words presented in the present disclosure are based on a relative position relationship shown in the drawings and cannot be used as an absolute limitation on the present disclosure.

To make the above purposes, features, and advantages of the present disclosure more comprehensive, the present disclosure is further described in detail in conjunction with the drawings and specific embodiments as follows.

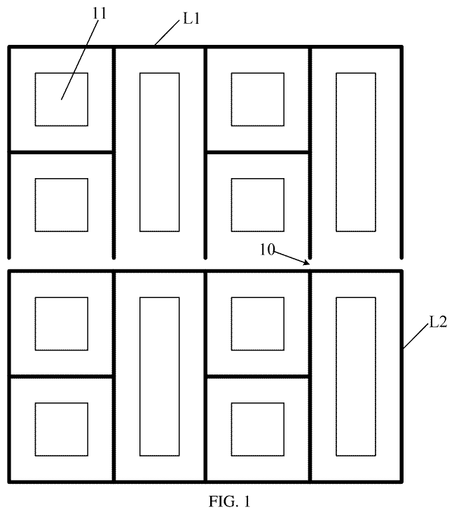

Referring to FIG. 1, which is a schematic layout diagram of a slit according to an embodiment of the present disclosure, it is assumed that an upper part and a lower part belong to two signal lines (also referred to as trace lines in the art), namely a signal line L1 and a signal line L2. In order to solve the problem of light leakage from a slit 10, in a possible implementation, as shown in FIG. 1, the slit 10 may be arranged at an edge of a sub-pixel 11.

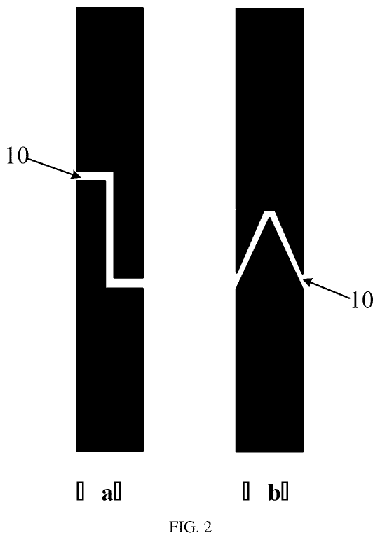

FIG. 2 is a schematic diagram of a special-shaped slit according to an embodiment of the present disclosure, where FIG. 2(a) shows an implementation of the special-shaped slit, and FIG. 2(b) shows another implementation of the special-shaped slit. In order to solve the problem of light leakage from the slit 10, in a possible implementation, as shown in FIG. 2, the slit 10 may be designed into a special-shaped structure, which can not only ensure that the touch traces are disconnected but also ensure that there is no large-viewing-angle light leakage.

FIG. 3 is a schematic diagram of a double-layer touch trace according to an embodiment of the present disclosure, where FIG. 3(a) shows an implementation of the double-layer touch trace, and FIG. 3(b) shows another implementation of the double-layer touch trace. In order to solve the problem of light leakage from the slit 10, in a possible implementation, as shown in FIG. 3, a touch trace may be added above the slit 10 to block the light leakage at the slit 10.

Further, in order to solve the problem of light leakage from the slit 10 to the greatest extent, a light modulation assembly may be arranged in the region of the slit 10 and includes the first film layer and the second film layer that are stacked in the first direction, with a refractive index of the first film layer being greater than a refractive index of the second film layer, when the large-viewing-angle light emitted by the light-emitting element in the display panel enters the light modulation assembly, total reflection can occur at an interface of the first film layer and the second film layer, and the light may not be refracted out from the interface, so that no light leakage can occur at the slit, thereby improving etching patterns and improving the display effect of the display panel.

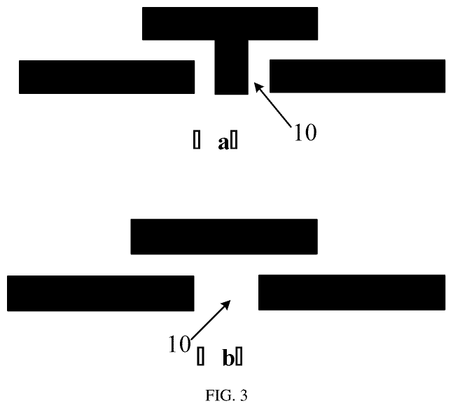

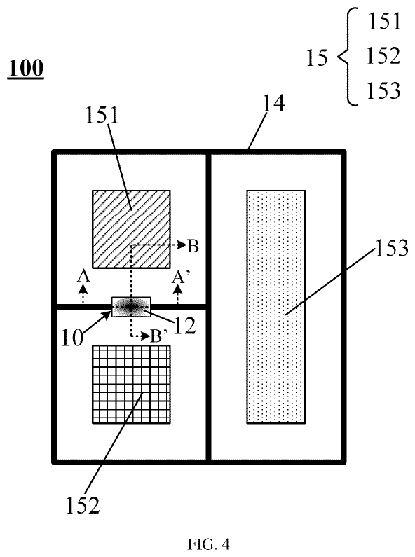

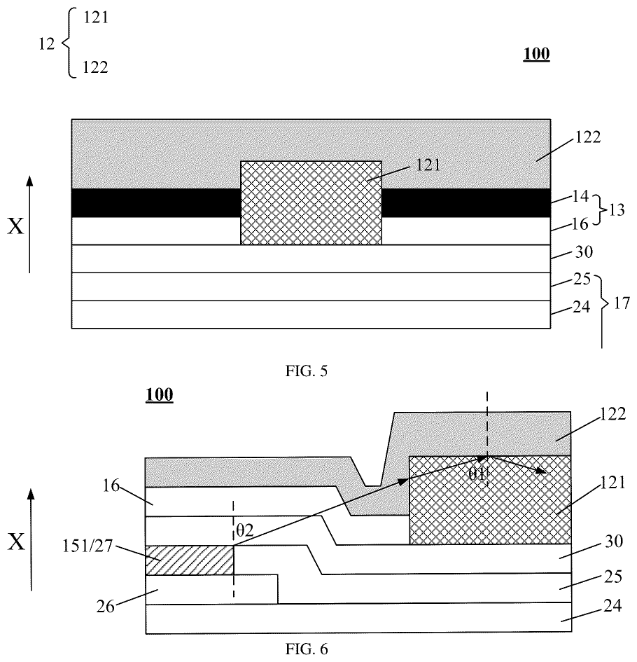

In an example, referring to FIG. 4, FIG. 5, and FIG. 6, where FIG. 4 is a schematic structural diagram of a display panel according to an embodiment of the present disclosure, FIG. 5 is a schematic cross-sectional view along a cutting line AA′ shown in FIG. 4 according to an embodiment of the present disclosure, and FIG. 6 is a schematic cross-sectional view along a cutting line BB′ shown in FIG. 4 according to an embodiment of the present disclosure, the display panel 100 according to the embodiments of the present disclosure includes a light modulation assembly 12 and a touch function layer 13.

The touch function layer 13 includes a plurality of touch traces 14, and at least part of the touch traces 14 is provided with a slit 10.

The light modulation assembly 12 is located in a region of the slit 10 and includes a first film layer 121 and a second film layer 122 that are stacked in a first direction X, and a refractive index of the first film layer 121 is greater than a refractive index of the second film layer 122. The first direction X is perpendicular to a plane of the touch function layer 13 and points to a light-emitting side of the display panel 100.

For example, the refractive index of the first film layer 121 may range from 1.5 to 1.7, and the refractive index of the second film layer 122 may range from 1.1 to 1.4.

In an example, in the embodiments of the present disclosure, the light-emitting side of the display panel 100 may also be understood as a display side of the display panel 100. As shown in FIG. 4 to FIG. 6, a light modulation assembly 12 composed of two film layers with different refractive indexes is provided in the region of the slit 10, so that the first film layer 121 and the second film layer 122 are stacked in the first direction X, and the refractive index of the first film layer 121 is greater than the refractive index of the second film layer 122. By using the principle that total reflection may occur when light enters a lower refractive index medium from a high refractive index medium, when the large-viewing-angle light emitted by the light-emitting element 15 in the display panel 100 enters the light modulation assembly 12, total reflection occurs at the interface between the first film layer 121 and the second film layer 122, and the light may not be refracted out from the interface between the first film layer 121 and the second film layer 122, so that no light leakage can occur at the slit 10. Other positions on the touch trace 14 without slits do not have a light leakage phenomenon due to their own light-shielding performance, so that the visual effect at the slit 10 is close to that at the touch trace 14, thereby improving the etching patterns and improving the display effect of the display panel 100.

For example, when light with an incident angle θ is emitted from the first film layer 121 to the second film layer 122, the refraction angle is equal to 90°. It can be understood that the incident angle θ is a critical angle. Therefore, when θ1>θ, all light rays undergo total reflection. Without considering the refraction of light rays when the light rays are emitted from the second film layer 122 to the first film layer 121, there is a relationship that θ2=θ1, that is, the light rays with θ2>θ undergo total reflection at the interface between the first film layer 121 and the second film layer 122 and may not be refracted out from the interface.

Considering that the light emitted by the light-emitting element 15 in the display panel 100 may be refracted when emitted from the second film layer 122 to the first film layer 121, since the refractive index of the first film layer 121 is greater than the refractive index of the second film layer 122, there is a relationship that the incident angle is greater than the refraction angle, that is, there is a relationship that θ2<θ1. Therefore, when θ2>θ, there must be a relationship that θ1>θ, that is, the light rays with θ2>θ undergo total reflection at the interface between the first film layer 121 and the second film layer 122 and may not be refracted out from the interface.

Generally, the light emitted from the light-emitting element 15 in the display panel 100 with θ2>θ may undergo total reflection at the interface between the first film layer 121 and the second film layer 122 and may not be refracted from the interface, which solves the problem of large-viewing-angle light leakage at the position of the slit 10, thereby improving the etching patterns and improving the display effect of the display panel 100.

It should be noted that values of θ1 and θ2 are related to parameters such as a ratio of the refractive index of the second film layer 122 to the first film layer 121 and a width-to-length ratio of the light modulation assembly 12, and may be designed according to actual conditions, which is not strictly limited in the embodiments of the present disclosure.

It should be noted that the touch traces 14 are arranged on a touch buffer layer 16 to provide a planarized buffer structure for the arrangement of the touch traces 14, so as to improve the stability of the touch traces 14.

In an example, each of the first film layer 121 and the second film layer 122 is respectively described by taking a transparent optical adhesive layer as an example. Exemplarily, the first film layer 121 and the second film layer 122 may be transparent overcoat (OC) adhesive layers. A material of the transparent OC adhesive layer includes but is not limited to polyethyl acrylate, polyurethane, or acrylic copolymer.

It should be noted that at least one light-emitting element 15 may be understood as forming one sub-pixel 11, and obviously, a plurality of light-emitting elements 15 may form one sub-pixel 11. In the embodiments of the present disclosure, an example where one light-emitting element 15 forms one sub-pixel 11 is used for description.

In order to achieve full-color display of the display panel 100, the light-emitting element 15 may include a red light-emitting element 151 for emitting red light, a green light-emitting element 152 for emitting green light, and a blue light-emitting element 153 for emitting blue light. In order to improve the display effect of the display panel 100, the light-emitting element 15 may further include a white light-emitting element for emitting white light, etc.

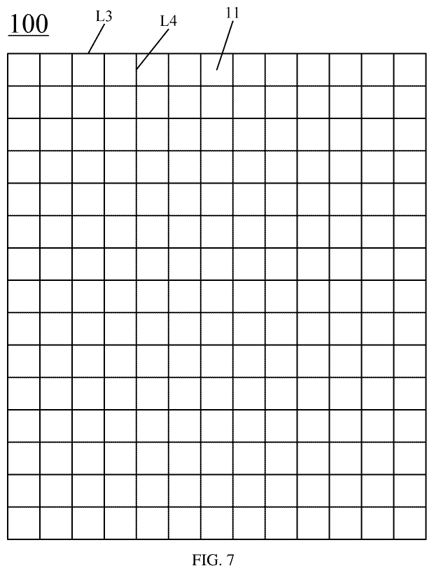

In an optional embodiment of the present disclosure, referring to FIG. 7 and FIG. 8, where FIG. 7 is a schematic structural diagram of another display panel according to an embodiment of the present disclosure, and FIG. 8 is a schematic structural diagram of a display function layer according to an embodiment of the present disclosure, the display panel 100 according to the embodiments of the present disclosure further includes: a display function layer 17. The touch function layer 13 is located on a light-emitting side of the display function layer 17. The display function layer 17 has a plurality of opening regions K and light-emitting elements 15. The light-emitting elements 15 are located in the opening regions K.

In an example, the display panel 100 according to the embodiments of the present disclosure includes traces L3 extending in a row direction and traces L4 extending in a column direction. The traces L3 and the traces L4 intersect to define a plurality of sub-pixels 11 arranged in an array. The traces L3 extending in the row direction may include Scan signal lines, Vref signal lines, DVH signal lines, and the like. The traces L4 extending in the column direction may include Data signal lines, PVDD signal lines, and the like.

As shown in FIG. 8, the display function layer 17 is located on one side of the substrate 18, and the substrate 18 includes but is not limited to a substrate made of a flexible insulating material, which has properties such as stretchability, bendability, or flexibility, and the material thereof includes but is not limited to a polyimide material (PI), a polycarbonate material (PC) or a polyethylene terephthalate material (PET).

As shown in FIG. 8, the display function layer 17 includes but is not limited to a first insulating layer 19, a second insulating layer 20, a third insulating layer 21, a fourth insulating layer 22, a passivation layer 23, a planarization layer 24 and a pixel definition layer 25. The pixel definition layer 25 has a plurality of opening regions K forming the sub-pixels 11. Taking an organic light-emitting display panel as an example, an anode layer 26, a light-emitting layer 27 and a cathode layer 28 are arranged in the opening region K where the sub-pixel 11 is formed, so as to form the light-emitting element 15 required for the sub-pixel 11.

As shown in FIG. 8, the display function layer 17 further includes a transistor 29, and the transistor 29 forms other functional circuits such as a pixel circuit. The transistor 29 includes an active layer 291, a gate 292, a source 293, and a drain 294. The active layer 291 is located on a side of the second insulating layer 20 away from the substrate 18, and the gate 292 is located on a side of the third insulating layer 21 away from the substrate 18. The source 293 and the drain 294 are located in a same layer and located on a side of the fourth insulating layer 22 away from the substrate 18. The passivation layer 23 is arranged on a side of the source 293 and the drain 294 away from the substrate 18, the planarization layer 24 is arranged on a side of the passivation layer 23 away from the substrate 18, and the pixel definition layer 25 is arranged on a side of the planarization layer 24 away from the substrate 18.

In an optional embodiment of the present disclosure, as shown in FIG. 5 and FIG. 6, the display panel 100 according to the embodiments of the present disclosure further includes: an encapsulation layer 30 located between the display function layer 17 and the touch function layer 13.

In an example, when forming the touch function layer 13, the touch function layer 13 is formed on the encapsulation layer 30. Referring to FIG. 9, which is a schematic structural diagram of another display panel according to an embodiment of the present disclosure, different touch electrodes 31 and signal lines 32 are formed by arranging slits 10. A main function of the signal line 32 is to transmit the touch electrical signals, and a main function of the touch electrode 31 is to serve as a touch sensing unit to realize touch detection. As shown in FIG. 4 and FIG. 9, the touch traces 14 form a metal grid. Part of the metal grid forms touch electrodes 31, Part of the metal grid forms signal lines 32, and the signal lines 32 are electrically connected to the touch electrodes 31. At least part of the touch traces 14 between the signal lines 32 is provided with slits 10, and/or the touch traces 14 between two adjacent touch electrodes 31 are provided with slits 10.

In other words, the signal lines 32 are connection lines connecting the touch electrodes 31 and the integrated circuit (IC). To ensure that the corresponding signal lines 32 between the touch electrodes 31 are not short-circuited, the slit 10 is arranged on at least part of the touch traces 14 between the signal lines 32, so as to divide the signal lines 32. Since each touch electrode 31 is independent, the slit 10 is arranged on the touch traces 14 between two adjacent touch electrodes 31 to divide the touch electrodes 31.

Further, to avoid the problem that the contour pattern of the touch electrode 31 is visible due to only providing slits 10 at the edge of the touch electrode 31, slits 10 may also be provided inside the touch electrode 31, so that the slits 10 are arranged more uniformly, thereby improving the display effect of the display panel 100.

According to the present disclosure, the light modulation assembly 12 is arranged in the region of the slits 10, solving the problem of large-viewing-angle light leakage at the position of the slits 10, and obviously solving the problem of visible contour patterns of the touch electrode 31. Therefore, in the embodiments of the present disclosure, It is possible to avoid providing slits 10 inside the metal grid forming the touch electrodes 31, and it is only necessary to provide slits 10 on the touch traces 14 between at least part of the signal lines 32, and/or on the touch traces 14 between two adjacent touch electrodes 31. Obviously, the number of slits 10 and the number of newly-added light modulation assemblies 12 can be reduced, thereby simplifying the process and reducing the cost.

The encapsulation layer 30 includes but is not limited to being formed by alternately stacking organic materials and inorganic materials, so as to effectively isolate substances such as water and oxygen. In an embodiment of the present disclosure, the touch function layer 13 is arranged with the encapsulation layer 30 as the substrate, and a glass substrate does not need to be provided for the touch function layer 13, thereby reducing a thickness of the entire display panel 100, and facilitating a lightweight and thin design of the display panel 100.

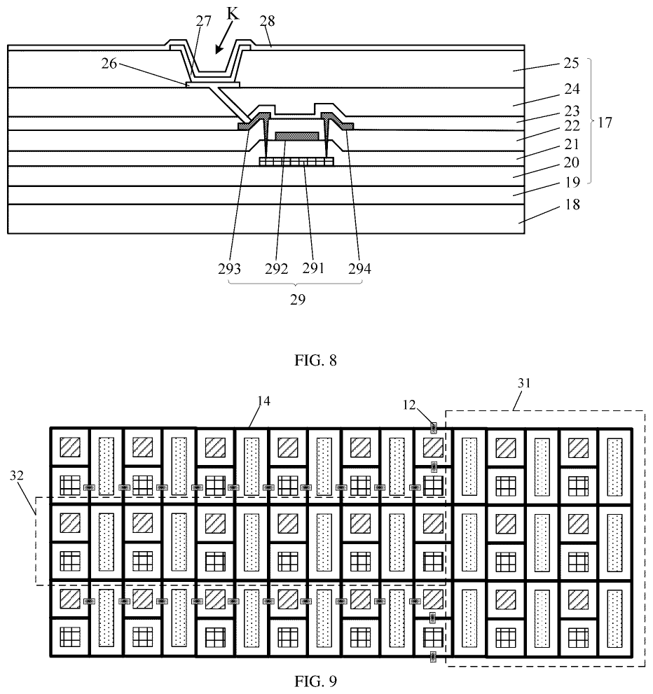

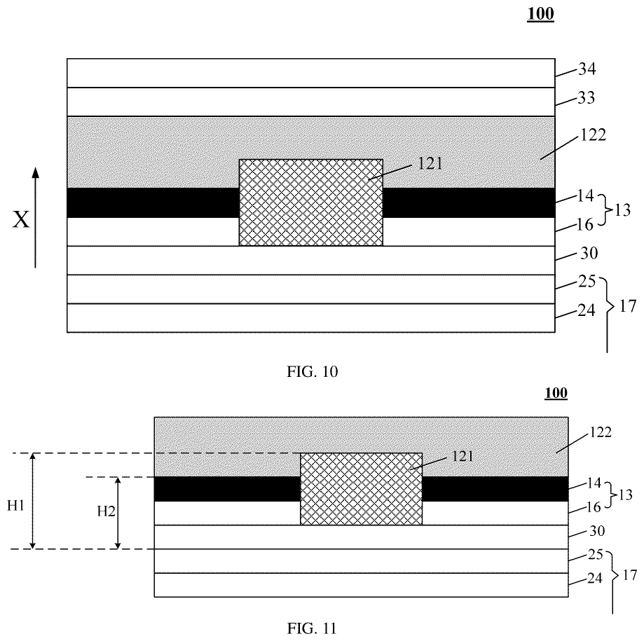

In an optional embodiment of the present disclosure, referring to FIG. 10, which is a schematic cross-sectional view of a display panel according to an embodiment of the present disclosure, the display panel 100 according to the embodiments of the present disclosure further includes: a polarizer 33 and a cover plate 34 that are sequentially located on a side of the touch function layer 13 away from the display function layer 17.

The second film layer 122 is located between the touch function layer 13 and the polarizer 33.

In an example, the cover plate 34 includes but is not limited to a glass cover plate. The purpose of improving the display effect of the display panel 100 is achieved by providing the polarizer 33. To improve the installation stability of components such as the polarizer 33 and the cover plate 34, a planarized transparent optical adhesive layer, such as a planarized transparent OC adhesive layer, is usually provided on a side of the touch function layer 13 away from the display function layer 17.

Therefore, in an embodiment of the present disclosure, the existing transparent optical adhesive layer of the display panel 100 can be used as the second film layer 122, and the refractive index of the newly added first film layer 121 can be determined based on the refractive index of the transparent optical adhesive layer, so that a refractive index of the newly added first film layer 121 is greater than a refractive index of the transparent optical adhesive layer, thereby realizing the design of the optical modulation assembly 12.

In other words, the embodiments of the present disclosure does not need to additionally design a new second film layer 122, and the existing transparent optical adhesive layer of the display panel 100 can be used as the second film layer 122, which is more conducive to the lightweight and thin design of the display panel 100 while reducing the cost.

In an optional embodiment of the present disclosure, in the first direction X, an orthographic projection of the second film layer 122 completely covers an orthographic projection of the first film layer 121.

In an example, it is assumed that in the first direction X, the orthographic projection of the second film layer 122 does not completely cover the orthographic projection of the first film layer 121, Part of a surface of the first film layer 121 away from the display function layer 17 is exposed, and the exposed surface is not covered by the second film layer 122, the light incident into the light modulation assembly 12 may be emitted from the exposed surface, so the problem of large-viewing-angle light leakage at the slits 10 may still exist.

Therefore, in the embodiments of the present disclosure, in the first direction X, the orthographic projection of the second film layer 122 completely covers the orthographic projection of the first film layer 121. In other words, in the first direction X, the orthographic projection of the second film layer 122 completely covers an orthographic projection of the slit 10, thereby ensuring that there is no large-viewing-angle light leakage at the slits 10 to the greatest extent.

In an optional embodiment of the present disclosure, referring to FIG. 11, which is a schematic cross-sectional view of another display panel according to an embodiment of the present disclosure, in the display panel 100, a distance between a surface of the first film layer 121 away from the display function layer 17 and a plane of the display function layer 17 is H1, a distance between a surface of the touch trace 14 away from the display function layer 17 and the plane of the display function layer 17 is H2, and H1≥H2.

In the embodiments of the present disclosure, under the relationship that H1>H2, the thickness of the first film layer 121 is relatively thick, and the height of the first film layer 121 may be at least greater than the depth at the position of the slit 10, so that the interface between the first film layer 121 and the second film layer 122 is raised, and more large-viewing-angle light emitted from the light-emitting element 15 in the display panel 100 is incident into the first film layer 121, so as to ensure that there is no large-viewing-angle light leakage at the slits 10 to the greatest extent.

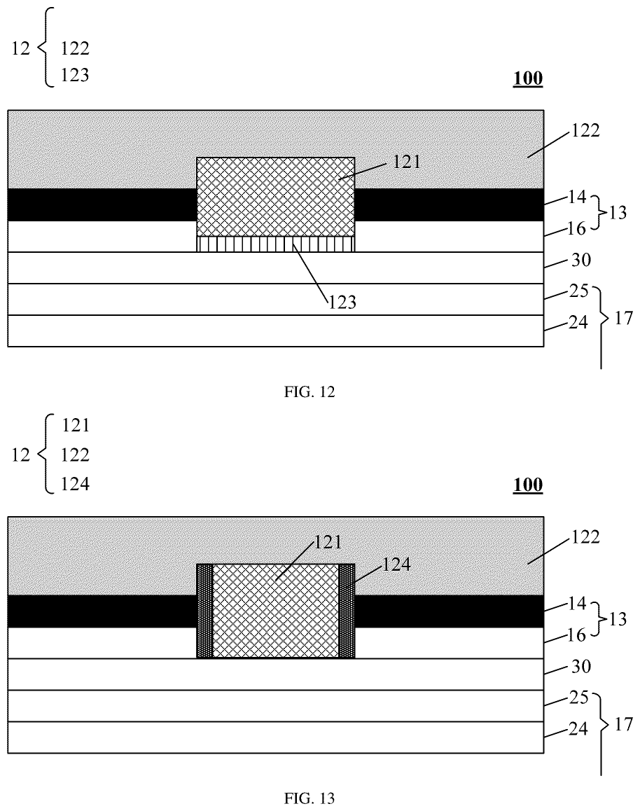

In an optional embodiment of the present disclosure, referring to FIG. 12, which is a schematic cross-sectional view of another display panel according to an embodiment of the present disclosure, the light modulation assembly 12 in the display panel 100 further includes: a third film layer 123 located on a side of the first film layer 121 away from the second film layer 122.

The refractive index of the first film layer 121 is greater than a refractive index of the third film layer 123.

Exemplarily, the refractive index of the third film layer 123 may range from 1.1 to 1.4.

In the embodiments of the present disclosure, since the second film layer 122 is located on a side of the first film layer 121 away from the display function layer 17, that is, an interface between the first film layer 121 and the second film layer 122 is also located on the side of the first film layer 121 away from the display function layer 17, the light incident on the light modulation assembly 12 is totally reflected by the interface and then is transmitted toward the backlight side of the display panel 100.

In order to prevent the part of light from exiting from the surface of the first film layer 121 facing the display function layer 17, which affects the display effect of the display panel 100, in an embodiment of the present disclosure, the third film layer 123 is arranged on the side of the first film layer 121 away from the second film layer 122, and the refractive index of the first film layer 121 is greater than the refractive index of the third film layer 123, so that the light incident on the interface between the first film layer 121 and the third film layer 123 is totally reflected again, preventing the light from continuing to transmit towards the backlight side of the display panel 100, thereby improving the display effect of the display panel 100.

It should be noted that the refractive index of the third film layer 123 and the refractive index of the second film layer 122 may be the same or different. Exemplarily, the refractive index of the first film layer 121 is M1, the refractive index of the second film layer 122 is M2, and the refractive index of the third film layer 123 is M3, where M1>M2, M1>M3, and M2≠M3; or M1>M2, M1>M3, and M2=M3.

It should be further noted that materials of the third film layer 123 and the second film layer 122 may be the same or different, which is not strictly limited in the embodiments of the present disclosure.

In an optional embodiment of the present disclosure, in the first direction X, an orthographic projection of the third film layer 123 completely covers an orthographic projection of the first film layer 121.

In the embodiments of the present disclosure, it is assumed that in the first direction X, the orthographic projection of the third film layer 123 does not completely cover the orthographic projection of the first film layer 121, part of the surface of the first film layer 121 facing the display function layer 17 is exposed, and the exposed surface is not covered by the third film layer 123, the light that is totally reflected by the interface between the first film layer 121 and the second film layer 122 and tends to be transmitted toward the backlight side of the display panel 100 may be emitted from the exposed surface, which still affects the display effect of the display panel 100.

Therefore, in the embodiments of the present disclosure, in the first direction X, the orthographic projection of the third film layer 123 completely covers the orthographic projection of the first film layer 121, so as to ensure that the light totally reflected by the interface between the first film layer 121 and the second film layer 122 cannot continue to be transmitted toward the backlight side of the display panel 100 to the greatest extent, thereby improving the display effect of the display panel 100 to the greatest extent.

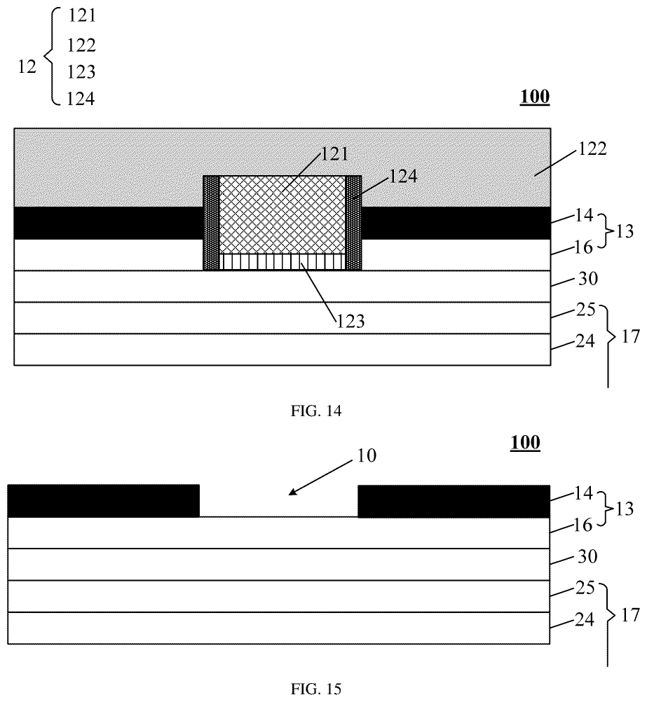

In an optional embodiment of the present disclosure, referring to FIG. 13 and FIG. 14, where FIG. 13 is a schematic cross-sectional view of another display panel according to an embodiment of the present disclosure, and FIG. 14 is a schematic cross-sectional view of another display panel according to an embodiment of the present disclosure, the light modulation assembly 12 in the display panel 100 further includes: a fourth film layer 124 covering a side wall of the first film layer 121.

The refractive index of the first film layer 121 is greater than a refractive index of the fourth film layer 124.

Exemplarily, the refractive index of the fourth film layer 124 may range from 1.1 to 1.4.

In the embodiments of the present disclosure, as shown in FIG. 13, since the second film layer 122 is located on a side of the first film layer 121 away from the display function layer 17, that is, an interface between the first film layer 121 and the second film layer 122 is also located on the side of the first film layer 121 away from the display function layer 17, the light incident on the light modulation assembly 12 is totally reflected by the interface and then is transmitted toward the backlight side of the display panel 100, and obviously, part of the light may also be incident on the side wall of the first film layer 121.

To prevent the part of light from exiting from the side wall of the first film layer 121, which affects the display effect of the display panel 100, in an embodiment of the present disclosure, the fourth film layer 124 is arranged at the side wall of the first film layer 121, and the refractive index of the first film layer 121 is greater than the refractive index of the fourth film layer 124, so that the light incident on the interface between the first film layer 121 and the fourth film layer 124 is totally reflected again, and the light cannot be emitted from the side wall of the first film layer 121, thereby improving the display effect of the display panel 100.

It should be noted that the refractive index of the fourth film layer 124 and the refractive index of the second film layer 122 may be the same or different. Exemplarily, the refractive index of the first film layer 121 is M1, the refractive index of the second film layer 122 is M2, and the refractive index of the fourth film layer 124 is M4, where M1>M2, M1>M4, and M2≠M4; or M1>M2, M1>M4, and M2=M4.

It should be further noted that materials of the fourth film layer 124 and the second film layer 122 may be the same or different, which is not strictly limited in the embodiments of the present disclosure.

As shown in FIG. 14, since the second film layer 122 is located on a side of the first film layer 121 away from the display function layer 17, that is, the interface between the first film layer 121 and the second film layer 122 is also located on the side of the first film layer 121 away from the display function layer 17, the light incident on the light modulation assembly 12 is totally reflected by the interface and then is transmitted toward the backlight side of the display panel 100. Since the third film layer 123 is located on a side of the first film layer 121 facing the display function layer 17, that is, the interface between the first film layer 121 and the third film layer 123 is also located on the side of the first film layer 121 facing the display function layer 17, the light incident on the light modulation assembly 12 is totally reflected by the interface and then is transmitted toward a light-emitting side of the display panel 100, and obviously, part of the light may also be incident on the side wall of the first film layer 121.

To prevent the part of light from exiting from the side wall of the first film layer 121, which affects the display effect of the display panel 100, in an embodiment of the present disclosure, the fourth film layer 124 is arranged at the side wall of the first film layer 121, and the refractive index of the first film layer 121 is greater than the refractive index of the fourth film layer 124, so that the light incident on the interface between the first film layer 121 and the fourth film layer 124 is totally reflected again, and the light cannot be emitted from the side wall of the first film layer 121, thereby improving the display effect of the display panel 100.

As shown in FIG. 14, based on the design of the first film layer 121, the second film layer 122, the third film layer 123, and the fourth film layer 124, the light incident on the light modulation assembly 12 may propagate inside the light modulation assembly 12, and may not be emitted from any angle, thereby solving the problem of large-viewing-angle light leakage at the slit 10 to the greatest extent and improving the display effect of the display panel 100 to the greatest extent.

It should be noted that the refractive index of the fourth film layer 124, the refractive index of the third film layer 123 and the refractive index of the second film layer 122 may be the same or different. Exemplarily, the refractive index of the first film layer 121 is M1, the refractive index of the second film layer 122 is M2, the refractive index of the third film layer 123 is M3, and the refractive index of the fourth film layer 124 is M4, where M1>M2, M1>M3, M>M4, and M2≠M3≠M4; or M1>M2, M1>M3, M1>M4, and M2=M3≠M4; or M1>M2, M1>M3, M1>M4, and M2≠M3=M4; or M1>M2, M1>M3, M1>M4, and M2=M3=M4.

It should be further noted that materials of the fourth film layer 124, the third film layer 123 and the second film layer 122 may be the same or different, which is not strictly limited in the embodiments of the present disclosure.

Based on the structure shown in FIG. 14, a manufacturing method thereof is further described below.

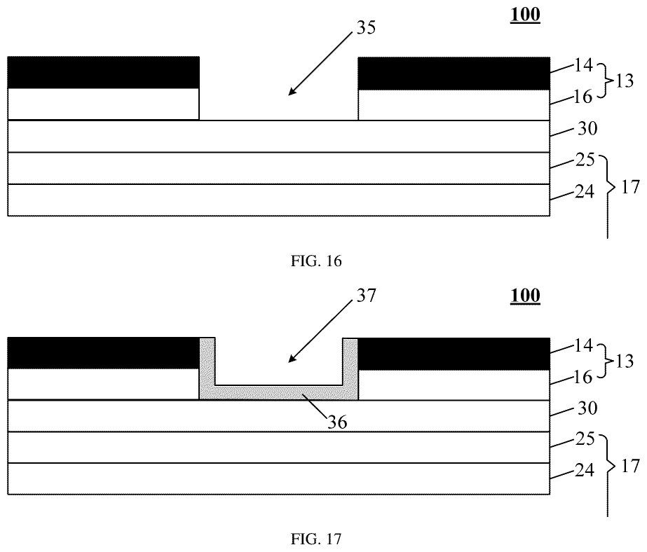

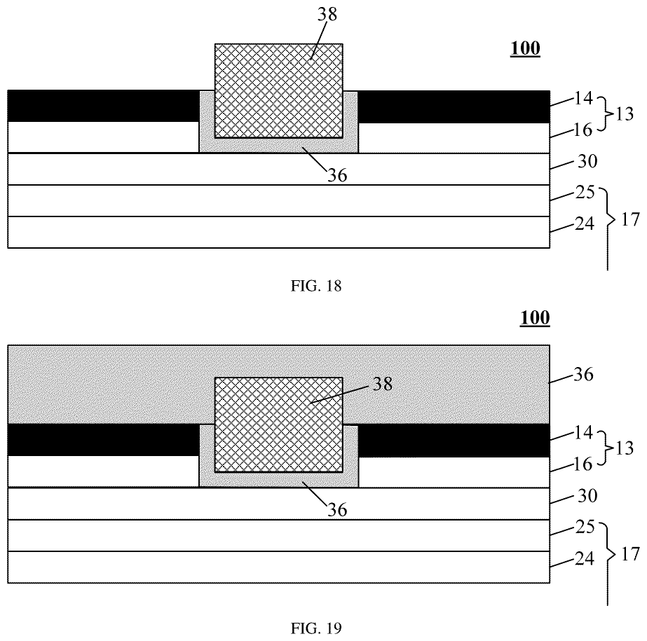

The following description is made by taking the example that the second film layer 122, the third film layer 123, and the fourth film layer 124 are made of the same material. FIG. 15 is a first partial schematic structural diagram corresponding to a method for preparing a display panel according to an embodiment of the present disclosure. FIG. 16 is a second partial schematic structural diagram corresponding to a method for preparing a display panel according to an embodiment of the present disclosure. FIG. 17 is a third partial schematic structural diagram corresponding to a method for preparing a display panel according to an embodiment of the present disclosure. FIG. 18 is a fourth partial schematic structural diagram corresponding to a method for preparing a display panel according to an embodiment of the present disclosure. FIG. 19 is a fifth partial schematic structural diagram corresponding to a method for preparing a display panel according to an embodiment of the present disclosure.
Step 1: As shown in FIG. 15, the touch trace 14 is etched to form a slit 10.
Step 2: As shown in FIG. 16, the touch buffer layer 16 is further etched based on the slit 10 to form a groove 35.
Step 3: As shown in FIG. 17, a first transparent optical adhesive layer 36 is deposited on the entire surface, and then the first transparent optical adhesive layer 36 is patterned, retaining only the first transparent optical adhesive layer 36 at the bottom and side walls of the groove 35.
Step 4: As shown in FIG. 18, a second transparent optical adhesive layer 38 is deposited on the entire surface, and then the second transparent optical adhesive layer 38 is patterned, retaining only the second transparent optical adhesive layer 38 in the groove 35 of the first transparent optical adhesive layer 36. A refractive index of the second transparent optical adhesive layer 38 is greater than a refractive index of the first transparent optical adhesive layer 36.
Step 5: As shown in FIG. 19, a first transparent optical adhesive layer 36 is deposited on the entire surface, so as to achieve full coverage of the second transparent optical adhesive layer 38 by the first transparent optical adhesive layer 36. The light incident on the light modulation assembly 12 may propagate inside the light modulation assembly 12, and may not be emitted from any angle, thereby solving the problem of large-viewing-angle light leakage at the slit 10 to the greatest extent and improving the display effect of the display panel 100 to the greatest extent.

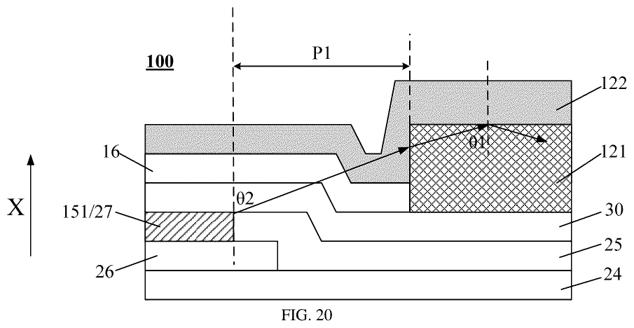

In an optional embodiment of the present disclosure, referring to FIG. 20, which is a schematic cross-sectional view of another display panel according to an embodiment of the present disclosure, in the display panel 100, the opening regions K include a target opening region arranged adjacent to the slit 10.

A distance between a surface of the first film layer 121 facing the target opening region and the target opening region is greater than or equal to 5 μm. That is, there is a relationship that P1≥5 μm.

In the embodiments of the present disclosure, the width of the light modulation assembly 12 is equal to the width of the slit 10, but the length of the light modulation assembly 12 may be greater than the width of the touch trace 14, extending toward the target opening region as much as possible, preferably close to the target opening region, so that more large-viewing-angle light emitted from the light-emitting element 15 in the display panel 100 is incident into the first film layer 121, so as to ensure that there is no large-viewing-angle light leakage at the slits 10 to the greatest extent.

Further considering issues such as process limitations, such as mask precision, a distance between the surface of the first film layer 121 facing the target opening region and the target opening region is greater than or equal to 5 μm, thereby reducing the process difficulty of preparing the display panel 100 on the premise of ensuring that there is no large-viewing-angle light leakage at the slit 10 to the greatest extent.

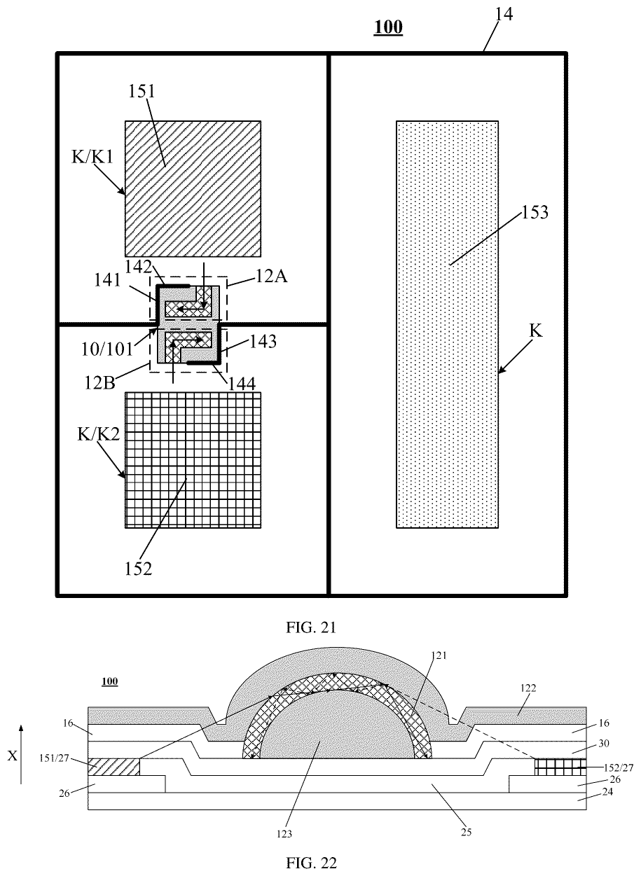

In an optional embodiment of the present disclosure, referring to FIG. 21, which is a schematic structural diagram of another display panel according to an embodiment of the present disclosure, in the display panel 100, the opening regions K include a first opening region K1 and a second opening region K2. The slit 10 is arranged on part of the touch traces 14 between the first opening region K1 and the second opening region K2. The slit 10 includes at least one target slit 101.

The light modulation assembly 12 in the target slit 101 includes a first light modulation assembly 12A and a second light modulation assembly 12B. The first light modulation assembly 12A is arranged close to the first opening region K1, and the second light modulation assembly 12B is arranged close to the second opening region K2.

The first light modulation assembly 12A includes a first surface facing the first opening region K1, and the second light modulation assembly 12B includes a second surface facing the second opening region K2.

The touch trace 14 at one side of the target slit 101 includes a first extension portion 141 and a second extension portion 142 that are connected in sequence. The first extension portion 141 extends in a direction close to the first opening region K1, and the second extension portion 142 covers part of the first surface.

The touch trace 14 on the other side of the target slit 101 includes a third extension portion 143 and a fourth extension portion 144 that are connected in sequence. The third extension portion 143 extends in a direction close to the second opening region K2, and the fourth extension portion 144 covers part of the second surface.

A length of the second extension portion 142 is G1, a length of the fourth extension portion 144 is G2, and a width of the target slit 101 is G, where G1+G2≥G.

In the embodiments of the present disclosure, a first light modulation assembly 12A and a second light modulation assembly 12B are independently provided in the region of the target slit 101. The first light modulation assembly 12A is configured to receive the large-view-angle light emitted by the light-emitting element 15 in the first opening region K1, and the second light modulation assembly 12B is configured to receive the large-view-angle light emitted by the light-emitting element 15 in the second opening region K2, thereby forming two independent optical paths.

Further, the touch traces 14 on both sides of the target slit 101 are respectively extended to form an L-shaped extension portion, that is, an L-shaped extension portion formed by the first extension portion 141 and the second extension portion 142, and an L-shaped extension portion formed by the third extension portion 143 and the fourth extension portion 144. When G1+G2≥G, the large-view-angle light emitted by the light-emitting element 15 in the first opening region K1 can only enter the first light modulation assembly 12A, and the large-view-angle light emitted by the light-emitting element 15 in the second opening region K2 can only enter the second light modulation assembly 12B, avoiding the problem of light crosstalk between the light-emitting elements 15 in different opening regions K, and playing a role in blocking the light paths between the sub-pixels 11, thereby improving the display effect of the display panel 100.

In an example, a surface exposed by the first surface is a surface of the first film layer 121 in the first light modulation assembly 12A, and/or a surface exposed by the second surface is a surface of the first film layer 121 in the second light modulation assembly 12B. In other words, the large-view-angle light emitted by the light-emitting element 15 in the first opening region K1 directly enters the first film layer 121 of the first light modulation assembly 12A, and the large-view-angle light emitted by the light-emitting element 15 in the second opening region K2 directly enters the first film layer 121 of the second light modulation assembly 12B, so as to solve the problem of light interference by interfaces of other film layers, thereby ensuring that the large-view-angle light emitted by the light-emitting element 15 in the opening region K enters the corresponding light modulation assembly 12 as much as possible.

In an example, the first light modulation assembly 12A and the second light modulation assembly 12B share one second film layer 122, thereby simplifying the difficulty of patterning the second film layer 122 and reducing the process difficulty.

In an optional embodiment of the present disclosure, referring to FIG. 22, which is a schematic structural diagram of another display panel according to an embodiment of the present disclosure, in the display panel 100, a surface of the first film layer 121 facing the second film layer 122 is a curved surface.

The curved surface protrudes toward a side away from the touch function layer 13.

In the embodiments of the present disclosure, the light modulation assembly 12 is an arc-shaped light modulation assembly 12. As shown in FIG. 22, light on the left side exits from the lower right after passing through the light modulation assembly 12, and light on the right side exits from the lower left after passing through the light modulation assembly 12, which ensures that there is no large-viewing-angle light leakage at the slit 10.

Further, the arc-shaped light modulation assembly 12 can increase the interface between the first film layer 121 and the second film layer 122, and the interface between the third film layer 123 and the first film layer 121, so as to perform total reflection on the light incident into the light modulation assembly 12 at as many angles as possible, thereby ensuring that there is no large-viewing-angle light leakage at the slit 10 to the greatest extent.

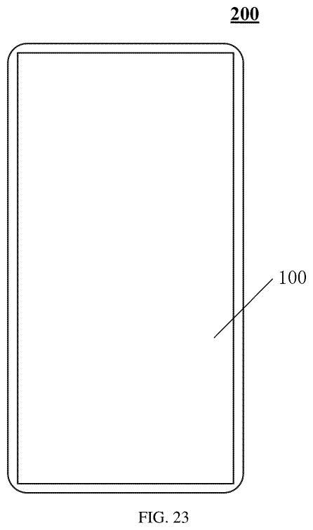

Based on the above embodiments of the present disclosure, accordingly, an embodiment of the present disclosure further provides a display device, referring to FIG. 23, which is a schematic structural diagram of a display device according to an embodiment of the present disclosure. The display device 200 includes the display panel 100 described in the above embodiments of the present disclosure, and the display device 200 may be any display device having a display function, such as a touch display screen, a mobile phone, a tablet computer, a notebook computer, an e-book or a television.

The display panel and the display device provided by the present disclosure have been described in detail above. Specific examples are used herein to describe the principles and implementations of the present disclosure, and the description of the above embodiments is only used to help understand the method and the core idea of the present disclosure. Meanwhile, for those skilled in the art, according to the idea of the present disclosure, there may be changes in the specific implementation and application scope. In summary, the content of the present specification should not be construed as limiting the present disclosure.

It should be noted that each embodiment in the present specification focuses on differences from other embodiments, and the same and similar parts between the embodiments may refer to each other.

It should be noted that, in this context, relational terms such as “first” and “second” are merely used to distinguish one entity from another entity or one operation from another operation, and do not necessarily require or imply any actual relationship or sequence between these entities or operations. Further, terms such as “include”, “comprise” or any other variations thereof are intended to cover a non-exclusive inclusion, such that a process, a method, an article, or a device that include a list of elements inherent to or also includes elements inherent to these processes, methods, articles, or devices. Without more limitations, an element defined by the statement “including a . . . ” does not exclude the existence of other identical elements in a process, a method, an article, or a device that include the element.

The above description of the disclosed embodiments enables one skilled in the art to implement or use the present disclosure. Various modifications to these embodiments will be apparent to those skilled in the art, and the general principles defined herein may be implemented in other embodiments without departing from the spirit or scope of the present disclosure. Accordingly, the present disclosure will not be limited to the embodiments described herein but should be interpreted to have the broadest scope in conformity with the principles and innovations disclosed in the present disclosure.

What is claimed is:

1. A display panel, comprising:
a touch function layer comprising a plurality of touch traces, wherein at least part of the plurality of touch traces is provided with a slit; and
a light modulation assembly located in a region of the slit, wherein the light modulation assembly comprises a first film layer and a second film layer that are stacked in a first direction, a refractive index of the first film layer is greater than a refractive index of the second film layer, and the first direction is perpendicular to a plane of the touch function layer and points to a light-emitting side of the display panel.

2. The display panel according to claim 1, further comprising:
a display function layer, wherein the touch function layer is located on a light-emitting side of the display function layer,
wherein the display function layer has a plurality of opening regions and a plurality of light-emitting elements, and the plurality of light-emitting elements are respectively located in the plurality of opening regions.

3. The display panel according to claim 2, further comprising:
an encapsulation layer located between the display function layer and the touch function layer.

4. The display panel according to claim 2, further comprising:
a polarizer and a cover plate that are sequentially located on a side of the touch function layer away from the display function layer,
wherein the second film layer is located between the touch function layer and the polarizer.

5. The display panel according to claim 1, wherein each of the first film layer and the second film layer is a transparent optical adhesive layer.

6. The display panel according to claim 5, wherein a material of the transparent optical adhesive layer is polyethyl acrylate, polyurethane, or acrylic copolymer.

7. The display panel according to claim 1, wherein in the first direction, an orthographic projection of the second film layer completely covers an orthographic projection of the first film layer.

8. The display panel according to claim 2, wherein a distance between a surface of the first film layer away from the display function layer and a plane of the display function layer is H1; and
a distance between a surface of the plurality of touch traces away from the display function layer and the plane of the display function layer is H2,
wherein H1≥H2.

9. The display panel according to claim 1, wherein the light modulation assembly further comprises:
a third film layer located on a side of the first film layer away from the second film layer,
wherein the refractive index of the first film layer is greater than a refractive index of the third film layer.

10. The display panel according to claim 9, wherein in the first direction, an orthographic projection of the third film layer completely covers an orthographic projection of the first film layer.

11. The display panel according to claim 9, wherein the light modulation assembly further comprises:
a fourth film layer covering a side wall of the first film layer,
wherein the refractive index of the first film layer is greater than a refractive index of the fourth film layer.

12. The display panel according to claim 1, wherein the light modulation assembly further comprises:
a fourth film layer covering a side wall of the first film layer,
wherein the refractive index of the first film layer is greater than a refractive index of the fourth film layer.

13. The display panel according to claim 2, wherein the plurality of opening regions comprise a target opening region arranged adjacent to the slit, and a distance between a surface of the first film layer facing the target opening region and the target opening region is greater than or equal to 5 μm.

14. The display panel according to claim 2, wherein the plurality of opening regions comprise a first opening region and a second opening region, touch traces between the first opening region and the second opening region are partially provided with slits, and the slits comprise at least one target slit;
the light modulation assembly in the at least one target slit comprises a first light modulation assembly and a second light modulation assembly, the first light modulation assembly is arranged close to the first opening region, and the second light modulation assembly is arranged close to the second opening region;
the first light modulation assembly comprises a first surface facing the first opening region, and the second light modulation assembly comprises a second surface facing the second opening region;
a touch trace on one side of the at least one target slit comprises a first extension portion and a second extension portion that are connected in sequence, the first extension portion extends in a direction close to the first opening region, and the second extension portion covers part of the first surface;
a touch trace on the other side of the at least one target slit comprises a third extension portion and a fourth extension portion that are connected in sequence, the third extension portion extends in a direction close to the second opening region, and the fourth extension portion covers part of the second surface; and
a length of the second extension portion is G1, a length of the fourth extension portion is G2, and a width of the at least one target slit is G, wherein G1+G2≥G.

15. The display panel according to claim 14, wherein a surface exposed by the first surface is a surface of the first film layer in the first light modulation assembly, and/or a surface exposed by the second surface is a surface of the first film layer in the second light modulation assembly.

16. The display panel according to claim 14, wherein the first light modulation assembly and the second light modulation assembly share one second film layer.

17. The display panel according to claim 1, wherein a surface of the first film layer facing the second film layer is a curved surface, the curved surface protrudes toward a side away from the touch function layer.

18. The display panel according to claim 1, wherein the plurality of touch traces form a metal grid, part of the metal grid forms touch electrodes, part of the metal grid forms signal lines, and the signal lines are electrically connected to the touch electrodes; and
wherein touch traces between the signal lines are partially provided with slits, and/or touch traces between two adjacent touch electrodes are provided with slits.

19. A display device, comprising a display panel,
wherein the display panel comprises:
a touch function layer comprising a plurality of touch traces, wherein at least part of the plurality of touch traces is provided with a slit; and
a light modulation assembly located in a region of the slit, wherein the light modulation assembly comprises a first film layer and a second film layer that are stacked in a first direction, a refractive index of the first film layer is greater than a refractive index of the second film layer, and the first direction is perpendicular to a plane of the touch function layer and points to a light-emitting side of the display panel.
